(19) United States
(12) Patent Application Publication
(10) Pub. No.: US 2009/0140376 A1
(43) Pub. Date: Jun. 4, 2009

(54) SEMICONDUCTOR DEVICE AND METHOD FOR MANUFACTURING THE DEVICE

(76) Inventor: Ho-Youn Kim, Nam-gu (KR)

Correspondence Address: SHERR & VAUGHN, PLLC, 620 HERNDON PARKWAY, SUITE 200, HERNDON, VA, 20170, US

(21) Appl. No.: 12/326,906

(22) Filed: Dec. 3, 2008

(30) Foreign Application Priority Data
Dec. 3, 2007 (KR) 10-2007-0124444

(51) Int. Cl. H01L 21/76; H01L 29/06

(52) U.S. Cl. 257/506; 438/423; 257/E21.54; 257/E29.018

(57) ABSTRACT

A method for forming a device isolation layer in a semiconductor substrate by destroying a lattice structure of the semiconductor substrate through a high-energy ion implantation process.

The present application claims priority under 35 U.S.C. §119 to Korean Patent Application No. 10-2007-0124444 (filed on Dec. 3, 2007), which is hereby incorporated by reference in its entirety.

### BACKGROUND

A semiconductor device may include one or more unit devices such as a transistor, a capacitor, a resistor, or the like that are preferably highly integrated. Accordingly, device isolation technology is required in order to achieve electrically independent characteristics of such devices. In a process for manufacturing the semiconductor device, the device isolation technology may be divided into a local oxidation of silicon (LOCOS) process and a shallow trench isolation (STI) process. The LOCOS process is a process that patterns a pad oxide film and a nitride film formed on and/or over a semiconductor substrate and then forms a device isolation layer by a selective oxidation process. The STI process involves forming the device isolation device by forming a trench at a predetermined depth in the semiconductor substrate, burying an insulating material in the trench, and then removing a portion of the insulating material other than the buried portion by a chemical mechanical polishing (CMP).

Since the LOCOS process generates a bird's beak phenomenon that may degrade the electrical characteristics of the device by lateral diffusion and lateral oxidation of a channel stop ion due to performing high-temperature oxidation at a long period of time, it has a limitation to applying to a process of 0.25 μm or less. In order to solve the problem of the LOCOS process, a current fine process of 0.25 μm or less mainly uses the STI process as a method for forming the device isolation film. Since a bird's beak is not generated when performing an STI process, it is advantageous to scale the semiconductor device and to have good insulating characteristics.

Hereinafter, a general STI process will be described with reference to the accompanying drawings.

FIGS. 1A to 1E show process cross-sectional views of a method for manufacturing a shallow trench device isolation layer.

As shown in FIG. 1A, a pad oxide film 11, a silicon nitride film 12, and a silicon oxide film 13 are sequentially deposited on and/or over an uppermost surface of a semiconductor substrate 10. Thereafter, a photosensitive film 14 for defining an active region and a field region of the semiconductor device is patterned. As shown in FIG. 1B, a trench T is formed at a predetermined depth by etching the silicon oxide film 13, the silicon nitride film 12, the pad oxide film 11, and the semiconductor substrate 10 using as a mask the photosensitive film 14.

As shown in FIG. 1C, a liner oxide film 15 is formed on and/or over walls of the trench T by performing a thermal oxidation process. The liner oxide film 15 performs a role of enhancing the adhesive between the semiconductor substrate 10 and an insulating film which is gap filled in the trench T in a subsequent process. As shown in FIG. 1D, the trench T is then completely buried by depositing a gap fill insulating film 16. Then, as shown in FIG. 1E, a CMP process using the silicon nitride film 12 as a polishing stop layer is performed. Thereafter, the silicon nitride film 12 is removed by a hot phosphoric acid solution and then the pad oxide film 11 is removed using a cleaning process, thereby forming the shallow trench isolation device 16.

In order to form such a device isolation layer using an STI process, a photolithography process, an insulating film depositing process, and a CMP process should be performed at least once, the etch process should be performed three times, and a wet cleaning process should be performed several times. Accordingly, such an STI process has a disadvantage of involving numerous and complex processes and is also expensive to perform.

### SUMMARY

Embodiments relate to a semiconductor device and a method for manufacturing the device including a process for forming a device isolation layer.

Embodiments relate to a semiconductor device and a method for manufacturing the device forming a device isolation region (film) by destructing a lattice structure of a semiconductor substrate by a high energy ion implantation process.

In accordance with embodiments, a method for manufacturing a semiconductor device may include at least one of the following: forming a mask layer on and/or over a substrate defining a field region and an active region divided by the field region and exposes the field region; forming a device isolation layer by selectively implanting ions into the field region of the semiconductor substrate using the mask layer as a mask; and then removing the mask layer.

In accordance with embodiments, a method may include at least one of the following: forming a mask layer pattern over a substrate to define a field region and an active region, the field region being exposed; and then forming a device isolation layer by selectively implanting ions into the field region of the semiconductor substrate using the mask layer pattern as a mask; and then removing the mask layer pattern.

In accordance with embodiments, a method may include at least one of the following: forming a mask layer pattern over a substrate to define a field region and an active region; and then simultaneously forming a device isolation layer in the field region of the semiconductor substrate and destroying a lattice structure of the semiconductor substrate by implanting ions at a predetermined energy threshold in the field region using the mask layer pattern as a mask; and then removing the mask layer pattern.

In accordance with embodiments, a semiconductor device may include at least one of the following: a semiconductor substrate; and a device isolation layer formed by destructing a lattice structure of the semiconductor substrate by selectively implanting ions into the field region of the semiconductor substrate.

### DRAWINGS

FIGS. 1A to 1E are process cross-sectional views for explaining a method for manufacturing a general shallow trench device isolation film;

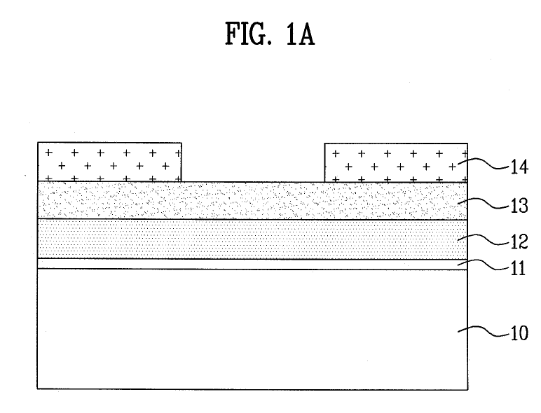

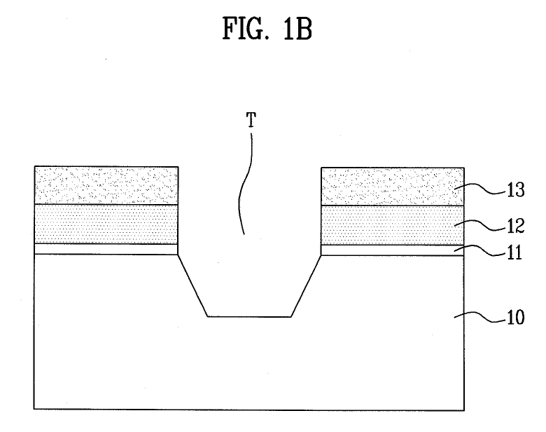

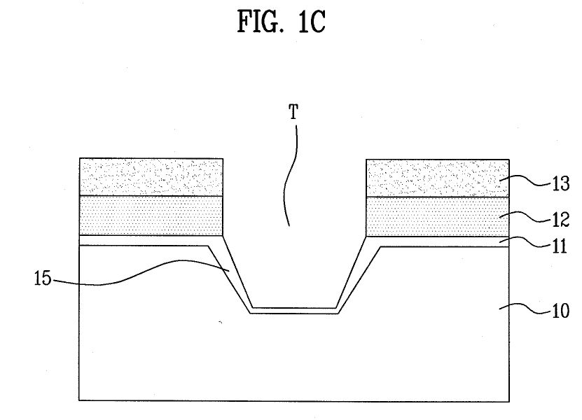

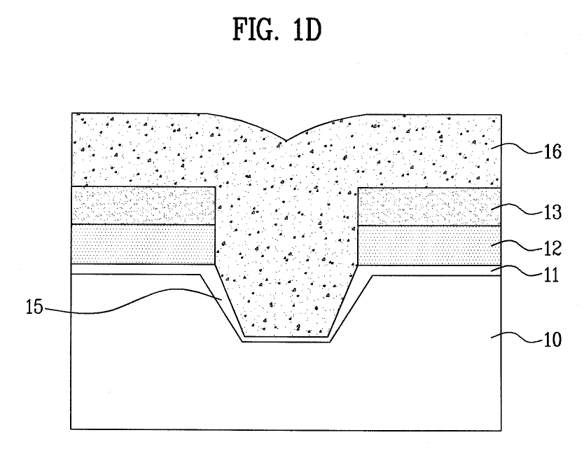

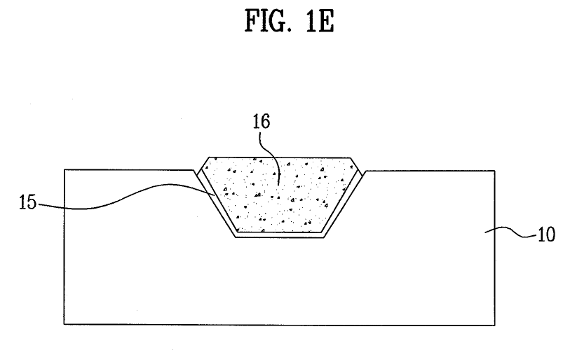

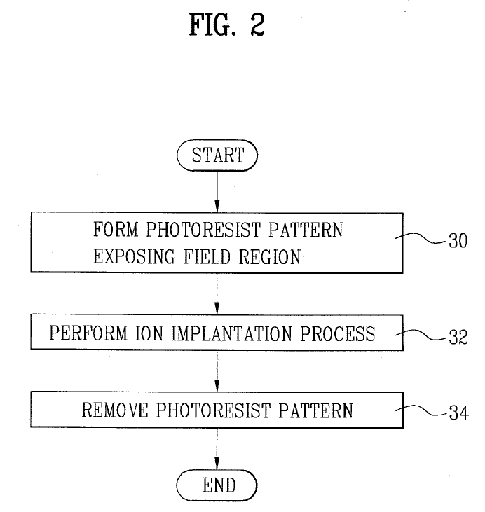

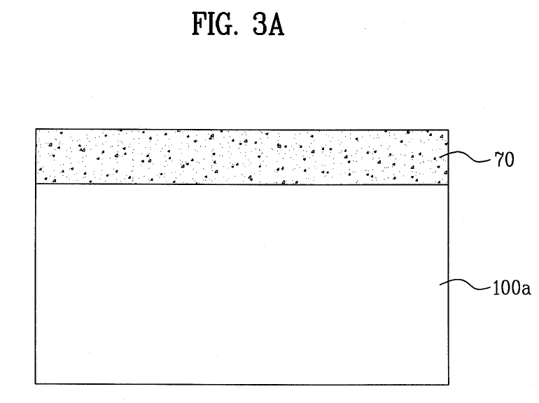

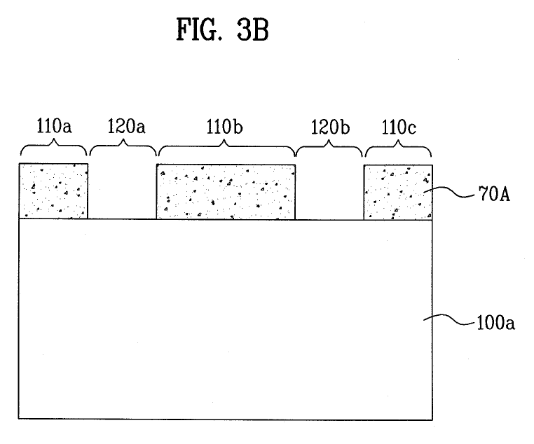

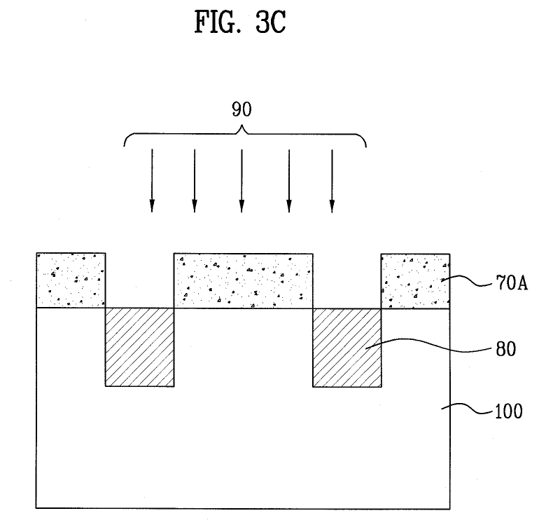

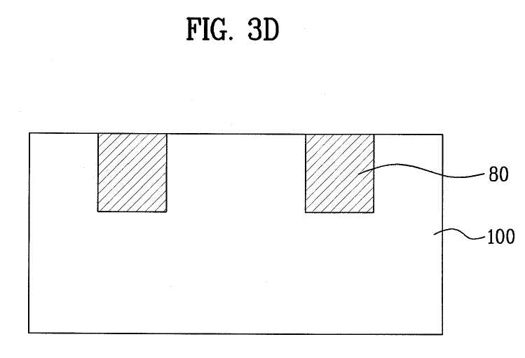

Example FIGS. 2 to 3 illustrate a method for forming a device isolation layer and a method for manufacturing a semiconductor device in accordance with embodiments.

### DESCRIPTION

Example FIG. 2 is a flow chart for explaining a method for forming a device isolation layer and example FIGS. 3A to 3D are process cross-sectional views of a method for manufacturing the semiconductor device in accordance with embodiments.

As shown in example FIGS. 3A and 3B, a mask layer 70A is formed on and/or over a semiconductor substrate 100a (step 30). The mask layer 70A defines field regions 120a, 120b and active regions 110a, 110b, and 110c and exposes field regions 120a, 120b. The active regions 110a, 110b, and 110c are regions that are spaced apart by the field regions 120a, 120b. In accordance with embodiments, the mask 70A may be in various forms. For example, the mask layer 70A may be a photo resist pattern. In this case, the photo resist pattern 70A may be formed as follows. As shown in example FIG. 3A, a photo resist 70 is applied on and/or over the semiconductor substrate 100a. Thereafter, as shown in FIG. 3B, a photo-lithography process is performed to pattern the photo resist 70, thereby forming as a mask layer the photo resist pattern 70A that exposes the field regions 120a, 120b. In other words, the field regions 120a, 120b of a positive-type photo resist 70 is exposed using the photo mask and the exposed photo resist is developed, making it possible to form the photo resist pattern 70A. Herein, the description is made under the assumption that the positive-type photo resist is used, but embodiments are not limited thereto and may use a negative-type photo resist.

After step 30, as shown in example FIG. 3C, the device isolation layer 80 is formed by selectively implanting ions 90 in the field regions 120a, 120b of the semiconductor substrate 100a exposed by the mask layer 70A (step 32). In accordance with embodiments, the amount of energy used for implanting ions 90 may have a value sufficient to destroy or otherwise remove the lattice structure of the semiconductor substrate 100a. For example, ions may be implanted by an energy level of at least 1 MeV. The use of such an energy level may form the device isolation layer 80 even in cases where the lattice structure of the silicon semiconductor substrate 100a is removed. Herein, the device isolation layer 80 may be referred as a device isolation region, but embodiments are not limited to this term. In accordance with embodiments, in order to remove the silicon lattice of the semiconductor substrate 100a, it is preferable that atomic weight of implanted ion is large. For example, the implanted ion 90 may be at least any one of germanium (Ge), Arsenic (As), and indium (In) ions.

As shown in example FIG. 3D, after step 32, the mask layer 70A remaining on and/or over the semiconductor substrate 100 in which the device isolation layer 80 is formed is removed (step 34). If the mask layer 70A is the photo resist pattern, the photo resist pattern may be removed by a strip process.

In accordance with embodiments, a method for manufacturing the semiconductor device removes or otherwise destroys the silicon lattice of a semiconductor substrate by implanting ions in the field regions using a high energy ion implantation process, thereby forming a device isolation layer 80 using a reduced number of processes. In other words, in order to form a device isolation layer by the method for manufacturing the semiconductor device in accordance with embodiments, a photolithography process, a high energy implantation process, and a cleaning process should be performed only once.

As shown in example FIG. 3D, a semiconductor device in accordance with embodiments includes a semiconductor substrate 100 and a device isolation layer 80 formed therein. The semiconductor substrate 100 is defined by the field regions 120a, 120b and the active regions 110a, 110b, and 110c. The device isolation layer 80 is a layer formed by removing or otherwise destroying the lattice structure of the semiconductor substrate 100a by performing a selective ion implantation process in the field regions 120a and 120b of the semiconductor substrate 100. For example, a MOS transistor may be formed in the active regions 110a, 110b, and 110c of the semiconductor substrate 100 and the device isolation layer 80 performs a role of electrically isolating the MOS transistors.

As described above, the semiconductor device and the method for manufacturing the device of the present invention remove a lattice structure of the semiconductor substrate through a high-energy ion implantation process to form the device isolation layer, such that simplification of the device isolation process can be promoted and the manufacturing costs can be reduced.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a mask layer pattern over a substrate to define a field region and an active region, the field region being exposed; and then
forming a device isolation layer by selectively implanting ions into the field region of the semiconductor substrate using the mask layer pattern as a mask; and then
removing the mask layer pattern.

2. The method of claim 1, wherein the mask layer pattern comprises a photo resist pattern.

3. The method of claim 2, wherein forming the mask layer pattern comprises:
forming a photo resist over the semiconductor substrate; and then
forming the photo resist pattern exposing the field region by patterning the photo resist.

4. The method of claim 3, wherein the photo resist is patterned through the performance of a photo lithography process.

5. The method of claim 1, wherein selectively implanting the ions comprises destroying a lattice structure of the semiconductor substrate

6. The method of claim 5, wherein the ions are implanted at a predetermined implantation energy.

7. The method of claim 6, wherein the predetermined implantation energy is at least 1 MeV.

8. The method of claim 1, wherein the ions comprises at least one of germanium (Ge), Arsenic (As), and indium (In) ions.

9. A method comprising:
forming a mask layer pattern over a substrate to define field regions and active regions in the substrate; and then
simultaneously forming a device isolation layer in the field region of the semiconductor substrate and destroying a lattice structure of the semiconductor substrate by implanting ions at a predetermined implantation energy in the field regions using the mask layer pattern as a mask; and then
removing the mask layer pattern.

10. The method of claim 9, wherein the mask layer pattern comprises a photo resist pattern.

11. The method of claim 10, wherein forming the mask layer pattern comprises:
forming a photo resist over the semiconductor substrate; and then
forming the photo resist pattern exposing the field region by patterning the photo resist.

12. The method of claim 11, wherein the photo resist is patterned through the performance of a photo lithography process.

13. The method of claim 9, wherein the predetermined implantation energy comprises at least 1 MeV.

14. The method of claim 9, wherein the ions comprises at least one of germanium (Ge), Arsenic (As), and indium (In) ions.

15. The method of claim 9, further comprising, after removing the mask layer pattern:
forming MOS transistors in active regions of the semiconductor substrate, wherein the device isolation layer electrically isolates the MOS transistors.

16. A device comprising:
a semiconductor substrate; and
a device isolation layer formed in the semiconductor substrate by selectively implanting ions into field regions of the semiconductor substrate at a predetermined implantation energy while also destroying a lattice structure of the semiconductor substrate.

17. The device of claim 16, wherein the predetermined implantation energy is at least 1 MeV.

18. The semiconductor device of claim 16, wherein the ions comprise at least one of germanium (Ge), Arsenic (As), and indium (In) ions.

19. The device of claim 16, further comprising MOS transistors formed in active regions of the semiconductor substrate.

20. The device of claim 19, wherein the device isolation layer electrically isolates the MOS transistors.
